(19) United States
(12) Patent Application Publication
(10) Pub. No.: US 2023/0324227 A1
(43) Pub. Date: Oct. 12, 2023

(54) PYROMETER CONTROLLED MULTI-WAFER CLEANING PROCESS

(71) Applicant: ASM IP Holding, B.V., Almere (NL)

(72) Inventors: Ernesto Suarez, Scottsdale, AZ (US); Amir Kajbafvala, Chandler, AZ (US); Caleb Miskin, Mesa, AZ (US); Bubesh Babu Jotheeswaran, Gilbert, AZ (US); Alexandros Demos, Scottsdale, AZ (US)

(21) Appl. No.: 18/190,696

(22) Filed: Mar. 27, 2023

Related U.S. Application Data
(60) Provisional application No. 63/324,440, filed on Mar. 28, 2022.

(51) Int. Cl. C23C 16/52; H01L 21/67; C23C 16/44; G01J 5/00

(52) U.S. Cl. CPC G01J 5/0007; C23C 16/4407; C23C 16/52; H01L 21/67115; H01L 21/67248

(57) ABSTRACT

A method of depositing an epitaxial material layer using pyrometer-based control. The method includes cleaning a reaction chamber of a reactor system, and, after the cleaning, providing a substrate within the reaction chamber. The method includes stabilizing a temperature of the substrate relative to a target deposition temperature. During stabilization, the heater assembly is operated with control signals to operate heaters in the heater assembly that are generated based on a direct measurement of the temperature of the substrate, such as with one to three pyrometers. The method includes, after the stabilizing of the temperature of the substrate, depositing an epitaxial material layer on a surface of the substrate. Then, for an additional number of substrates, the method involves repeating the steps of providing a substrate within the reaction chamber, stabilizing the temperature of the substrate, and depositing an epitaxial material layer on the substrate followed by another chamber cleaning.

### FIELD OF THE DISCLOSURE

The present disclosure generally relates to gas-phase reactors and systems and to methods of using the reactors and systems. More particularly, the disclosure relates to methods of depositing epitaxial material and to systems for depositing the epitaxial material with enhanced throughput and uniformity control.

### BACKGROUND OF THE DISCLOSURE

Gas-phase reactors, such as chemical vapor deposition (CVD) reactors, can be used for a variety of applications, including depositing and etching materials on a substrate surface. For example, gas-phase reactors can be used to deposit epitaxial layers on a substrate to form semiconductor devices, flat panel display devices, photovoltaic devices, microelectromechanical systems (MEMS), and the like.

A typical gas-phase epitaxial reactor system includes a reactor including a reaction chamber, one or more precursor and/or reactant gas sources fluidly coupled to the reaction chamber, one or more carrier and/or purge gas sources fluidly coupled to the reaction chamber, a gas injection system to deliver gases (e.g., precursor/reactant gas(es) and/or carrier/purge gas(es)) to the reaction chamber, a susceptor to retain and heat a substrate, and an exhaust source fluidly coupled to the reaction chamber. Further, epitaxial reactor systems can include one or more heaters (e.g., lamps) and/or temperature measurement device (e.g., a thermocouple). The lamps can be used to heat areas within the reaction chamber. The thermocouple can be used to indirectly measure the temperature within the reaction chamber (e.g., of the susceptor).

During an epitaxial deposition process, a layer of epitaxial material is deposited onto or grows on a surface of a substrate. In addition, material can be deposited onto walls of the reaction chamber, the susceptor, and the like within the reaction chamber. The material that deposits on the walls of the reaction chamber and the susceptor can affect a thermal and/or chemical environment within the reaction chamber, which, in turn, can affect deposition (e.g., rate and/or uniformity) of material that is subsequently deposited onto a surface of a substrate. Further, once material deposits onto the walls of the reaction chamber and/or susceptor, the material can be difficult to remove. Therefore, the reaction chamber is typically cleaned after each substrate or deposition process to remove residue from an interior of the reaction chamber.

In high volume manufacturing (HVM), it is desirable to optimize film deposition process run rate or throughput. Epitaxial films are engineered for composition and thickness uniformity while controlling the process temperature and flow stability. In forming epitaxial films, the process needs to have a stable substrate temperature (e.g., wafer temperature) when starting the deposition step. In traditional epitaxial deposition methodology, the reaction chamber is cleaned between each substrate (which may be labeled every-wafer clean (EWC) processing), and the chamber cleaning step and/or recipe may be labeled an etch or pre-recipe step or process.

Cleaning the reaction chamber involves use of high temperatures and chlorinated precursors, in many cases, such as hydrochloric acid (HCI). For example, the etch or pre-recipe process may require heating the reaction chamber and components therein including the susceptor to temperatures in the range of 900 to 1250° C. (e.g., temperatures in the range of 1000 to 1100° C.) and providing HCI flows in the range of 10 to 30 standard liter per minute (slm) (e.g., 15-25 slm, 18-24 slm, or the like). In contrast, deposition process temperatures are considerably lower such as in the range of 550 to 900° C. (e.g., 600 to 850° C., 600 to 750° C., or the like). A large thermal inertia is created by the high-temperature clean recipe that is undesirably carried into the main deposition process, which happens at a lower temperature regime.

Presently, the chamber cleaning and stabilization of chamber temperatures prior to deposition are controlled based on temperatures sensed by one or more thermocouples located in the susceptor or substrate support. With thermocouple-based control of the heaters and/or processes, long stabilization times are required at the beginning of the deposition recipe, which can limit or reduce the process run-rate and lower overall throughput. Hence, there remains a demand for improved systems and methods for depositing epitaxial materials on a surface of a substrate that better optimize high run rates per reaction chamber while maintaining equal process growth.

### SUMMARY OF THE DISCLOSURE

Various embodiments of the present disclosure relate to improved methods and systems for depositing epitaxial material on a surface of a substrate. While the ways in which various embodiments of the present disclosure address drawbacks of prior systems and methods are discussed in more detail below, in general, various embodiments of the disclosure provide methods and systems that can be used to deposit epitaxial material in a time- and/or cost-effective manner. Exemplary methods can be used to process multiple substrates and/or perform multiple processes without cleaning an interior of a reaction chamber, while maintaining or even improving within substrate and/or substrate-to-substrate uniformity of film thickness, composition, and/or the like.

In brief, the method of depositing an epitaxial material layer(s) involves use of multi-wafer cleaning (MWC) processes in which the chamber clean or etch (or pre-recipe) step or process is performed after deposition on two to twenty-five or more substrates (e.g., wafers) rather than after each substrate. Significantly, pyrometer control or pyrometer-based control is utilized to control temperatures during the chamber clean and stabilization steps as well as during deposition. This allows more timely control, when compared with indirect measurements provided by thermocouple control, over heaters in the reactor system based on direct temperature measurements of the susceptor upper surface (e.g., the surface used to receive and support wafers) during chamber cleaning and of a substrate upper surface during stabilization (and deposition) processes. Pyrometer control provides significant advantages of being able to reduce the stabilization time since the substrate temperature is being monitored directly with one or more pyrometers instead of a secondary thermal effect as is the case with thermocouple-based controls. The description provides a high throughput, thermally stable MWC processing that is useful for SiGe:B (or other SiGe) epitaxial films or grown or deposited layers including a stabilization of substrate temperatures prior to deposition.

In accordance with exemplary embodiments of the disclosure, a method of depositing an epitaxial material layer is provided. The method includes cleaning a reaction chamber of a reactor system, and, after the cleaning, providing a substrate within the reaction chamber. The method further includes, with a heater assembly, stabilizing a temperature of the substrate relative to a target deposition temperature. During stabilization, the heater assembly is operated by control signals generated by a controller to operate heaters in the heater assembly based on a direct measurement of the temperature of the substrate. The method next includes, after the stabilizing of the temperature of the substrate, depositing an epitaxial material layer on a surface of the substrate. Then, for an additional number of substrates, the method involves repeating the providing a substrate within the reaction chamber, the stabilizing the temperature of the substrate, and the depositing an epitaxial material layer on the surface of the substrate and further repeating the cleaning of the reaction chamber.

In some embodiments, the direct measurement of the temperature of the substrate is provided by operating a pyrometer to sense a temperature of a single point on the surface of the substrate. In other cases, the direct measurement of the temperature of the substrate is provided by operating a center pyrometer and an edge pyrometer to sense temperatures at a center point and an edge point on the surface of the substrate. In still other implementations, the direct measurement of the temperature of the substrate is provided by operating two or more pyrometers to sense temperatures at two or more points on the surface of the substrate.

The control signals can be generated by a heater controller that includes a proportional-integral-derivative (PID) controller based on a comparison of the temperature of the substrate sensed by a pyrometer to the target deposition temperature. In these and other exemplary embodiments of the method, the stabilizing of the temperature of the substrate is performed for a stabilization time in the range of 30 to 90 seconds. The step of repeating the providing a substrate within the reaction chamber, the stabilizing the temperature of the substrate, and the depositing an epitaxial material layer on the surface of the substrate can be performed at least four times, whereby the step of cleaning the reaction chamber is performed after five or more substrates have been processed.

According to some embodiments of the method, the reaction chamber includes a susceptor with an upper surface for supporting the substrate provided within the reaction chamber and wherein, during the cleaning of the reaction chamber, the heater assembly is operated by control signals generated in response to a temperature of the upper surface of the susceptor sensed by the pyrometer. In these and other embodiments, the step of depositing an epitaxial material layer includes a controller operating to generate control signals to operate the heaters in the heater assembly based on the direct measurement of the temperature of the surface of the substrate by the pyrometer. With use of pyrometer-based control, the epitaxial material layer may include a silicon germanium film, and a range of mean thickness of the silicon germanium film may be less than 3.5 Angstroms (e.g., a 60 percent improvement over thermocouple-based control).

According to other exemplary aspects of the description, a reactor system is provided for depositing an epitaxial material layer. The system includes a reaction chamber, and, in the reaction chamber, a susceptor for supporting a substrate. The system also includes a heat assembly with a plurality of heaters to heat the substrate on the susceptor. In the system, a pyrometer is provided for directly measuring a temperature of the substrate. A controller is included in the system for controlling, after a chamber cleaning process, the plurality of heaters based on the temperature of the substrate to stabilize the temperature of the substrate relative to a target deposition temperature. The controlling can be performed for a stabilization time prior to initiating deposition of layer of material on the substrate supported on the susceptor.

The stabilization time may be in the range of 30 to 90 seconds. In some embodiments of the system, the controller includes a proportional-integral-derivative (PID) controller generating control signals to control one or more heaters in the heater assembly based on a comparison of the temperature of the substrate sensed by the pyrometer to the target deposition temperature. In these or other embodiments, the chamber cleaning process is performed after two or more of the substrates are processed including the controller stabilizing the substrate temperature for the stabilization time prior to initiating the deposition of a layer of material on the substrate. The controller may further control the plurality of heaters based on the temperature of the substrate to stabilize the temperature of the substrate relative to a target deposition temperature during the deposition of the layer of material on the substrate and based on a temperature of the susceptor sensed by the pyrometer during the chamber cleaning process.

In accordance with additional exemplary embodiments of the disclosure, a method of forming a device structure is provided. Exemplary device structures can include, for example, silicon, silicon germanium, or one or more layers comprising silicon and one or more layers comprising silicon germanium. By way of examples, the device structure can be used to form a field effect transistor, such as a gate all around device.

In accordance with yet additional exemplary embodiments of the disclosure, a system for performing a method and/or for forming a device structure is provided.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a method in accordance with at least one exemplary embodiment of the present disclosure.

FIG. 2 schematically illustrates a device structure formed in accordance with at least one exemplary embodiment of the disclosure.

FIG. 3 schematically illustrates another device structure formed in accordance with at least one exemplary embodiment of the disclosure.

FIG. 4 schematically illustrates a reactor system in accordance with at least one exemplary embodiment of the disclosure.

FIG. 5 illustrates another reactor system in accordance with examples of the disclosure.

FIG. 6 illustrates another device structure formed in accordance with at least one exemplary embodiment of the disclosure.

FIG. 7 is a simplified top perspective view of a portion of a reactor system with a temperature monitoring assembly of the present description for providing dual-zone temperature control while stabilizing substrate temperature.

FIG. 8 is a control schematic of a reactor system including the temperature monitoring components along with a controller configured to provide dual-zone control of lamps of a heating (or heater) assembly such as during stabilization of substrate temperatures.

FIG. 9 is a graph showing wafer temperature prior to stabilization, during stabilization, and after stabilization (e.g., during initiation of deposition).

FIG. 10 is a graph showing mean in wafer (SiGe) per wafer in a five-wafer MWC process for pyrometer-based control and for thermocouple-based control.

FIG. 11 is a graph showing uniformity of both mean SiGe and mean Ge percent in a ten-wafer MWC process using pyrometer-based control.

It will be appreciated that elements in the figures are illustrated for simplicity and clarity and have not necessarily been drawn to scale. For example, the dimensions of some of the elements in the figures may be exaggerated relative to other elements to help to improve the understanding of illustrated embodiments of the present disclosure.

### DETAILED DESCRIPTION OF EXEMPLARY EMBODIMENTS OF THE DISCLOSURE

The description of exemplary embodiments provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features.

The present disclosure generally relates to methods and systems for depositing epitaxial material. Exemplary methods and systems can be used to process substrates, such as semiconductor wafers, during the manufacture of devices, such as semiconductor devices, flat panel display devices, photovoltaic devices, microelectromechanical systems (MEMS), and the like. By way of examples, exemplary systems and methods described herein can be used to form or grow epitaxial layers (e.g., one component, two component and/or doped semiconductor layers) on a surface of a substrate. Exemplary systems can further be used to provide clean interior surfaces of the reaction chamber after a number (e.g., greater than 2, 3, 5, 10, 15, 25, or the like) of process or substrate runs.

As used herein, the terms “precursor” and/or “reactant” can refer to one or more gases/vapors that take part in a chemical reaction or from which a gas-phase substance that takes part in a reaction is derived. The chemical reaction can take place in the gas phase and/or between a gas phase and a surface (e.g., of a substrate or reaction chamber) and/or a species on a surface (e.g., of a substrate or a reaction chamber).

As used herein, a “substrate” refers to any material having a surface onto which material can be deposited. A substrate may include a bulk material such as a Group IV (e.g., silicon, such as single crystal silicon) or other semiconductor material, such as Group III-V or Group II-VI semiconductor material, or may include one or more layers overlying the bulk material. Further, the substrate may include various topologies, such as trenches, vias, lines, and the like formed within or on at least a portion of a layer of the substrate. In accordance with examples of the disclosure, a substrate includes a surface that includes crystalline semiconductor material.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas.

The term “inert gas” can refer to a gas that does not take part in a chemical reaction and/or does not become a part of a film matrix to an appreciable extent. Exemplary inert gases include helium, argon, and any combination thereof. A carrier can be or include an inert gas. A dilution gas can be or include an inert gas or hydrogen.

As used herein, the term “film” and/or “layer” can refer to any continuous or noncontinuous structure and material, such as material deposited by the methods disclosed herein. For example, film and/or layer can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous.

As used herein, a “structure” can be or include a substrate as described herein. Structures can include one or more layers overlying the substrate, such as one or more layers formed according to a method as described herein. Device portions can be or include structures.

As used herein, the term “epitaxial layer” can refer to a substantially single crystalline layer upon an underlying substantially single crystalline substrate or layer.

As used herein, the term “chemical vapor deposition” can refer to any process wherein a substrate is exposed to one or more gas-phase precursors, which react and/or decompose on a substrate surface to produce a desired deposition.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

Embodiments of the description provide a reactor system configured and operated to implement a pyrometer controlled multi-wafer cleaning (MWC) process. This process is suited for implementation using a wide variety of pyrometer configurations and numbers (e.g., one to three or more pyrometers measuring wafer/substrate and/or susceptor upper surface temperatures), and, additionally, this process is suited for used with a number of deposition recipes and processes with those specifically described herein being intended as exemplary useful deposition processes suited to pyrometer-based heater control during stabilization as well as chamber cleaning, which is performed between multiple wafer runs (e.g., two to twenty-five or more substrates run through deposition between chamber cleaning or etching processes or recipes).

Semiconductor manufacturing processes involving deposition of epitaxial material, for example, often involve performing an etching or cleaning process on the reaction chamber and components therein between each wafer or substrate or between multiple wafers or substrates. Throughput is limited by the need to periodically clean the reaction or process chamber. Chamber cleaning requires heating the chamber to a temperature much greater than the deposition temperatures, such 1000 to 1200° C., for some processes (e.g., an HCI-based etch) used for cleaning. The temperature differential requires that the reaction chamber and its components be cooled after cleaning to the target deposition temperature and stabilized in a range of temperatures about the target deposition temperature. In prior processes and systems, stability was demonstrated though indirect temperature measurements acquired from a susceptor thermocouple.

In contrast, the pyrometer controlled MWC process uses direct temperature measurements of the substrate (or its upper surface) and the susceptor (or its upper surface) using one or more pyrometers during the stabilization and deposition steps/processes and the chamber cleaning or etch steps/processes, respectively. The use of direct temperature measurements using pyrometers eliminates the time lag between substrate temperature becoming stable and the susceptor thermocouple recognizing that substrate temperature has stabilized. The result is a significantly shortened stabilization time (e.g., a stabilization time in the range of 30 to 90 seconds or the like providing a reduction in stabilization time of 300 seconds or more per substrate) before deposition is initiated for each substrate, which significantly increases throughput (e.g., from 4.2 wafers per hour (wph) to 7.2 wph up to 7.7 wph or more per reaction chamber using pyrometer-based control). Surprisingly, use of pyrometer control over stabilization also increased deposition uniformity among the substrates of a multi-wafer or multi-substrate run between cleanings. Specifically, without being bound by a particular theory or mode of operation, it is believed that employment of both a center pyrometer (having a field of view including a center surface portion of the wafer) and an edge pyrometer (having a field of view including an edge portion of the wafer) limits within-wafer thickness variation during multi-wafer or multi-substate runs between cleanings. Further, use of pyrometer control during stabilization resulted in elimination (or at least significant reduction) of the first wafer effect phenomenon (e.g., first wafer may be approximately 25° C. hotter than later wafers) that had sometimes resulted in varying quality of deposition on a first wafer after chamber cleaning when thermocouple-based control was utilized. Moreover, it was found that applying a precoat material after cleaning and prior to loading the first wafer further limited the first wafer effect phenomenon when both center pyrometers and edge pyrometers are employed for temperature control.

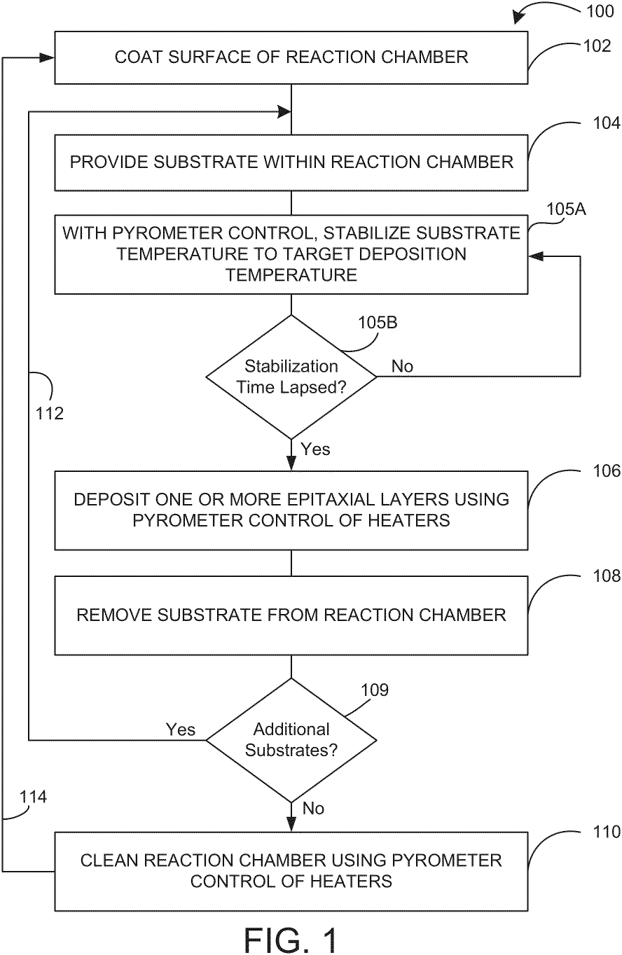

Turning now to the figures, FIG. 1 illustrates an exemplary method 100 in accordance with examples of the disclosure. Method 100 can be used to deposit an epitaxial material layer, e.g., during formation of a device structure. In the illustrated example, method 100 includes coating a surface of a reaction chamber (step 102), providing a substrate within a reaction chamber (step 104), stabilizing temperatures relative to a target deposition temperature (steps 105A and 105B), depositing one or more epitaxial material layers on a surface of the substrate using pyrometer control of heaters (step 106), removing the substrate from the reaction chamber (step 108), cleaning the reaction chamber using pyrometer control of heaters (step 110), and repeating steps 104-108, in between performance of cleaning 110 and/or coating steps 102, for additional substrates (loop 112, which may be repeated 2 to 10 times such as to provide a MWC process for 5 to 10 substrates or another useful number of wafers between etching 110).

During step 102, a precoat material is deposited onto a surface within a reaction chamber. The surfaces can include, for example, surfaces of a wall or walls of the reaction chamber, a surface or surfaces of a susceptor, surfaces of various inlets to or outlets from the reaction chamber, and the like. By way of examples, the surface within the reaction chamber includes at least a top surface of a susceptor. To deposit the precoat material, one or more precursors and/or reactants are provided to the reaction chamber. The precursors can desirably include at least one element in common with the epitaxial material to be deposited. For example, when the epitaxial material to be deposited onto the substrate includes silicon, at least one of the precursors can include silicon. Further, when the epitaxial material to be deposited onto the substrate includes germanium, at least one of the precursors can include germanium.

Exemplary precursors for use during step 102 include halides, such as silicon halides. In some embodiments, the silicon halide compound can include, for example, a silicon halide having the general formula given as: SiₓW_{y}H_{z}, wherein “W” is a halide selected from the group consisting of Fluorine (F), Chlorine (CI), Bromine (Br), and Iodine (I), “x” and “y” are integers greater than zero, and “z” is an integer greater than or equal to zero. In some embodiments, the silicon halide precursor may be selected from the group consisting of silicon fluorides (e.g., SiF₄), silicon chlorides (e.g., SiCl₄), silicon bromides (e.g., SiBr₄), and silicon iodides (e.g., Sil₄). In some embodiments, the silicon halide precursor may comprise silicon tetrachloride (SiCl₄).

In some embodiments, precursor may comprise a silane, such as, for example, silane (SiH₄), disilane (Si₂H₆), trisilane (Si₃H₈), tetrasilane (Si₄H₁₀) or higher order silanes with the general empirical formula SiₓH₍₂ₓ₊₂₎. By way of examples, the precursor can be or include one or more of silicon tetrachloride (SiCl₄), trichloro-silane (SiCl₃H), dichlorosilane (SiCl₂H₂), monochlorosilane (SiCIH₃), hexachlorodisilane (HCDS), octachlorotrisilane (OCTS), a silicon iodide, a silicon bromide; or an amino-based precursor, such as hexakis(ethylamino)disilane (AHEAD) and SiH[N(CH₃)₂]₃(3DMASi), a bis(dialkylamino)silane, such as BDEAS (bis(diethylamino)silane); a mono(alkylamino)silane, such as di-isopropylaminosilane; or an oxysilane based precursor, such as tetraethoxysilane Si(OC₂H₅)₄.

In some cases, the precursor preferentially includes a halogen. It is thought that precursors including a halogen may preferentially cause deposition on a susceptor, relative to deposition on a reaction chamber, which may provide for better deposition uniformity of subsequently deposited epitaxial layers on a substrate surface. In some cases, a dilution gas, such as hydrogen, or an inert gas can be provided to the reaction chamber during step 102. Additionally or alternatively, a carrier gas, such as an inert gas, can be provided to the reaction chamber during step 102.

In accordance with further examples of the disclosure, an etchant can be provided to the reaction chamber during step 102. The etchant can be provided from the same source vessel as the precursor or separately provided to the reaction chamber. Exemplary etchants include halides, such as compounds comprising one or more of fluorine (F), chlorine (CI), bromine (Br), and iodine (I). By way of examples, the etchant can be or include hydrogen chloride and/or one or more halogen gases, such as F₂, Cl₂, Br₂, and I₂. Similar to use of a precursor including a halogen, use of an etchant is thought to cause higher deposition on a susceptor during step 102, relative to a reaction chamber wall, which may provide for better deposition uniformity of subsequently deposited epitaxial layers on a substrate surface.

During step 102, a temperature within the reaction chamber (e.g., of a susceptor and/or reaction chamber wall) can be about 850° C. to about 1050° C., about 850° C. to about 950° C., or about 900° C. to about 950° C. A pressure within the reaction chamber can be about 10 Torr to about 1 ATM, about 10 to about 500 Torr, or about 15 Torr to about 200 Torr. A flowrate of the precursor to the reaction chamber can be about 50 sccm to about 1000 sccm, about 100 sccm to about 900 sccm, or about 200 sccm to about 700 sccm.

A thickness of material deposited during step 102 (e.g., the precoat material) can vary according to various factors. By way of examples, when the epitaxial material comprises silicon, a thickness of the layer of material on the susceptor can be about 50 to about 5000 Angstroms, about 50 to about 2000 Angstroms, or about 0.5 to about 20 microns. When the epitaxial material comprises germanium (e.g., silicon germanium), a thickness of the layer of material on the susceptor can be about 10 to about 5000 Angstroms, about 10 to about 1000 Angstroms, about 10 to about 500 Angstroms, about 0.5 microns to about 10 microns, or about 0.5 microns to about 20 microns.

During step 104, one or more substrates are loaded into the reaction chamber. During this step, the temperature of the reaction chamber (e.g., of a susceptor and/or reaction chamber wall) may decrease to about 200° C. to about 900° C., about 200° C. to about 700° C., about 500° C. to about 900° C., or about 500° C. to about 650° C. A pressure within the reaction chamber can be about 10 Torr to about 80 Torr, about 10 Torr to about 200 Torr, or about 5 Torr to about 600 Torr.

Once a substrate is loaded into the reaction chamber, the reaction chamber can be brought to or stabilized at a desired temperature deposition temperature and pressure for step 106 of depositing one or more epitaxial layers. In this regard, the method 100 includes stabilizing the temperature of the substrate provided on the susceptor in step 104 to a temperature range that includes the target deposition temperature using pyrometer control. Particularly, during stabilization in step 105A, one or more pyrometers are used to determine a substrate temperature by processing electromagnetic radiation emitted from an upper surface of the substrate, and this substrate temperature is used to generate control signals to control operations of one or more heaters in the reactor system used to heat the reaction chamber, the susceptor, and the received substrate. Once a system controller determines a stabilization time has elapsed at step 105B, deposition is initiated at step 106. The temperature within the reaction chamber during steps 104 and/or 106 can be lower than a temperature within the reaction chamber during step 102.

In some cases, method 100 can include a bake step prior to step 106 (such as before step 105A or as part of step 105A). In these cases, a temperature within the reaction chamber can be about 700° C. to about 1200° C., about 750° C. to about 1000° C., or about 700° C. to about 900° C. during the bake step. A pressure within the reaction chamber during the bake step can be about 2 Torr to about 1 ATM, about 2 Torr to about 400 Torr, or 2 Torr to about 200 Torr. After step 104 and any bake step, the reaction chamber (e.g., a susceptor within the reaction chamber) can be brought to a desired deposition temperature in step 105A using pyrometer-based control of the system heaters.

After the stabilization is achieved via pyrometer-based heater control during the stabilization time, one or more epitaxial layers are deposited onto a surface of a substrate in step 106, and during such deposition, pyrometer control can be used to maintain the substrate at the target deposition temperature (or in a range, such as plus/minus 2° C. about the target deposition temperature). The precursors used to deposit the epitaxial material can include a semiconductor material, such as a Group IV, Group III-V, and/or Group II-VI semiconductor material. By way of illustrative examples, the precursor and the epitaxial material can include silicon. Suitable silicon precursors for depositing epitaxial silicon include any of the silicon precursors noted above. By way of examples, dichlorosilane (DCS), silane (SiH₄), and/or disilane (Sl₂H₆) can be used as a reactant. Suitable germanium precursors for deposition of an epitaxial layer comprising germanium (e.g., germanium or silicon germanium layers) include germane, digermane, and the like.

The deposition temperature can be about 350° C. to about 950° C., about 350° C. to about 800° C., or about 600° C. to about 800° C. A pressure within the reaction chamber during the bake step can be about 2 Torr to about 1 ATM, about 2 Torr to about 400 Torr, or about 2 Torr to about 200 Torr. A flowrate of a silicon precursor can be about 10 sccm to about 700 sccm, or 10 sccm to about 300 sccm; flowrate of a germanium precursor can be about 10 sccm to about 990 sccm, about 10 sccm to about 220 sccm, or about 10 sccm to about 85 sccm; either or which flowrates can be with or without a carrier gas.

In accordance with examples of the disclosure, one or more (e.g., alternating) layers of silicon and/or silicon germanium (e.g., a single layer of silicon germanium) can be deposited during step 106. In accordance with these examples, the silicon can be, for example, intrinsically doped or include a dopant, such as germanium, boron, arsenic, phosphorous in a concentration of about 1 to about 40 atomic percent. The silicon germanium layer can include from greater than 60 at% silicon, greater than 90 at% silicon, or about 18 to about 35 or about 20 to about 30 atomic percent germanium and about 70 to about 80 or about 65 to about 80 atomic percent silicon. A number of epitaxial material layers can vary. In accordance with examples of the disclosure, about 1 to about 8, or about 1 to about 6 or about 1 to 4 or about 1 to 3 silicon epitaxial material layers alternating with about 0 to about 8, or about 0 to about 6, or about 0 to 4, silicon germanium epitaxial material layers can be deposited onto the substrate surface during step 106. In accordance with other examples of the disclosure, the one or more layers can include a single layer of silicon germanium. Such layers can be used to, for example, form a channel region of a field effect transistor.

During step 108, the one or more substrates are removed from the reaction chamber. During this step, the reaction chamber may be allowed to cool, e.g., to a temperature of about 550 to about 650 or about 500 to about 800 and brought to a desired pressure for substrate transfer. Once the substrate(s) are removed from the reaction chamber, steps 104-108 can be repeated a number of times before performing the reaction chamber clean in step 110. For example, loop 112 can be repeated 2 to 10 or 2 to 25 or more times prior to method 100 proceeding to step 110, with exemplary useful runs for the MWC process 100 involving processing of 5 or 10 or more wafers/substrates with steps 104-108 between cleanings at step 110.

During step 110, the reaction chamber is cleaned using an etchant to remove material deposited during steps 102 and 106 such as with an HCI-based clean recipe, and the temperatures may again be controlled to follow those defined in a cleaning process recipe with the pyrometers based on a measured temperature of the susceptor (e.g., an upper surface of the susceptor used to receive a wafer/substrate but after a substrate is removed in step 108). Exemplary etchants include halides, such as compounds comprising one or more of fluorine (F), chlorine (CI), bromine (Br), iodine (I), and the like. By way of examples, the etchant can be or include one or more halogen gases, such as hydrogen chloride, F₂, Cl₂, Br₂, and I₂. A temperature within the reaction chamber during step 110 can be about 800° C. to about 1250° C., about 950° C. to about 1200° C., about 950° C. to about 1100° C., or about 850° C. to about 1250° C. A pressure within the reaction chamber during step 110 can be about 50 Torr to about 1 ATM, about 50 Torr to about 600 Torr, or about 200 Torr to about 500 Torr. A flowrate of an etchant during step 110 can be about 12 to about 22 standard liters per meter (SLM) or about 0.5 to about 30 SLM.

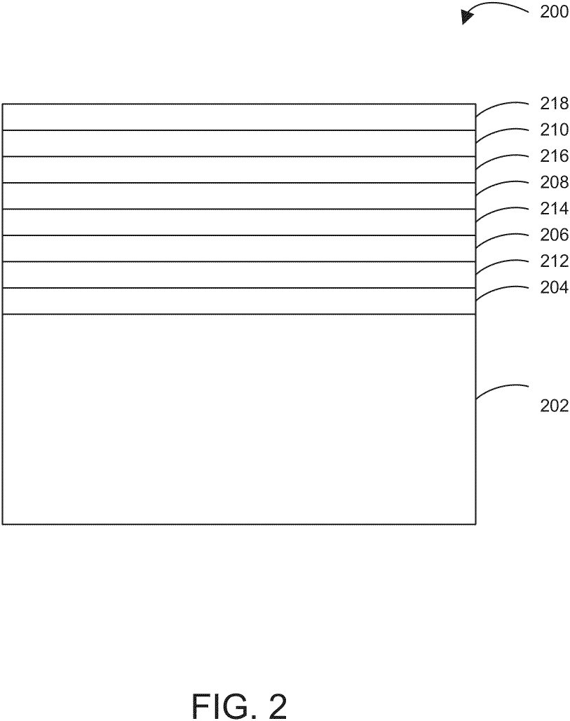

FIG. 2 illustrates a device structure (sometimes referred to simply as structure) 200 formed in accordance with exemplary embodiments of the disclosure. Structure 200 includes a substrate 202 and a plurality of epitaxial layers 204-218 formed overlying substrate 202. In particular, structure 200 include a plurality of epitaxial silicon germanium layers 204, 206, 208, and 210 alternating with a plurality of silicon layers 212, 214, 216, and 218. Epitaxial layers 204-218 can be formed, for example, during step 106 of method 100. As noted above, a plurality of structures, such as structure 200, can be formed prior to performing a step of cleaning the reaction chamber. Further, using techniques described herein including pyrometer-based control during stabilization, layer uniformity of film thickness and composition is improved, compared to performing stabilization using susceptor thermocouple control of heaters. Further, substrate-to-substrate composition and thickness uniformity is improved using techniques described herein (including removal of the first wafer effect phenomenon using pyrometer-based control during at least stabilization.

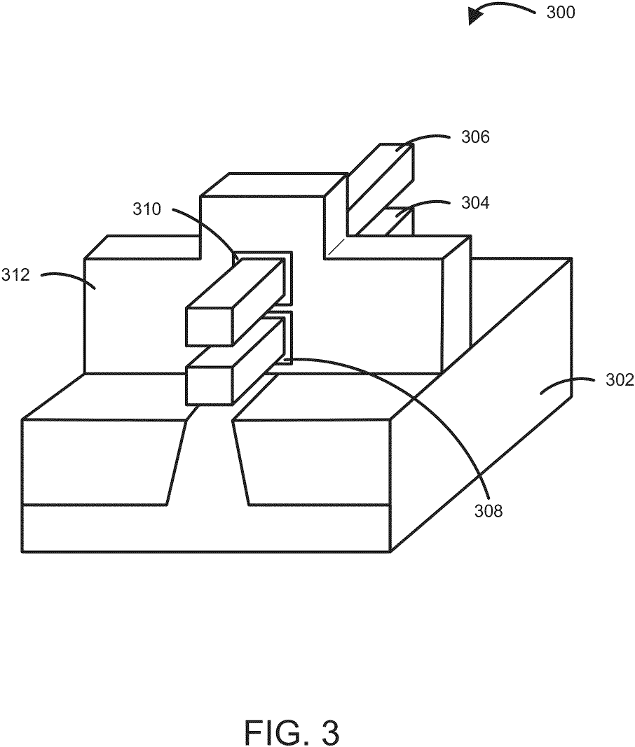

FIG. 3 illustrates a device structure (sometimes referred to simply as structure) 300 in accordance with further examples of the disclosure. Structure 300 can be used to form a gate all around field effect transistor. Structure 200 can be used to form structure 300 by etching the epitaxial silicon layers and removing the epitaxial silicon germanium layers. Structure 300 includes a substrate 302, one or more silicon channel regions or nanowires 304, 306, dielectric material 308, 310, and a conducing material 312. Silicon channel regions or nanowires 304, 306 can be formed, for example, by forming epitaxial layers according to method 100.

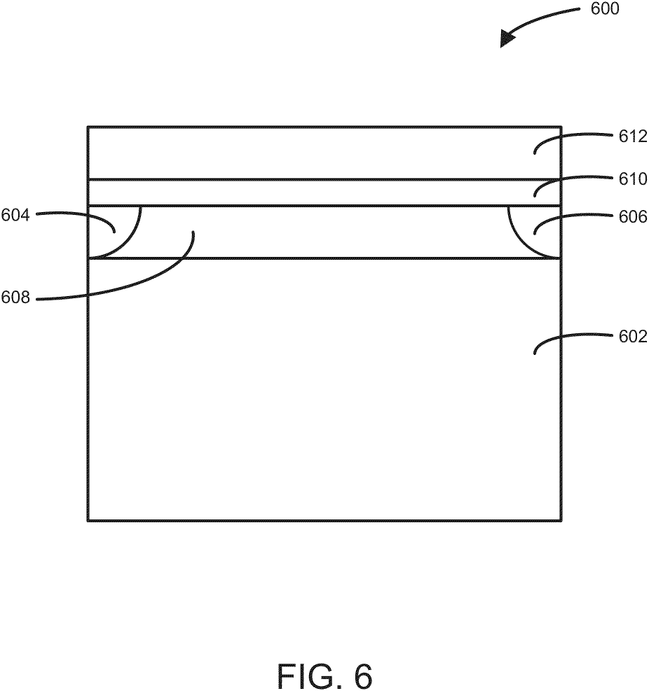

FIG. 6 illustrates another device structure 600 in accordance with examples of the disclosure. Device structure 600 is suitable for forming metal oxide semiconductor field effect transistors (MOSFET) (e.g., p-MOSFET) devices. In the illustrative example, device structure 600 includes a substrate 602, a source region 604, a drain region 606, and a SiGe channel region 608 formed between source region 604 and drain region 606. SiGe channel region 608 can be formed on multiple substrates according to a method, such as method 100, described herein. In accordance with examples of the disclosure, a thickness of SiGe channel region 608 can be about 40 Angstroms to about 150 Angstroms or about 80 Angstroms to about 120 Angstroms or about 40 Angstroms to about 100 Angstroms. Device structure 600 also include a dielectric layer 610, such as silicon oxide and/or a metal oxide and conducting material 612, such as polysilicon and/or on or more metal layers.

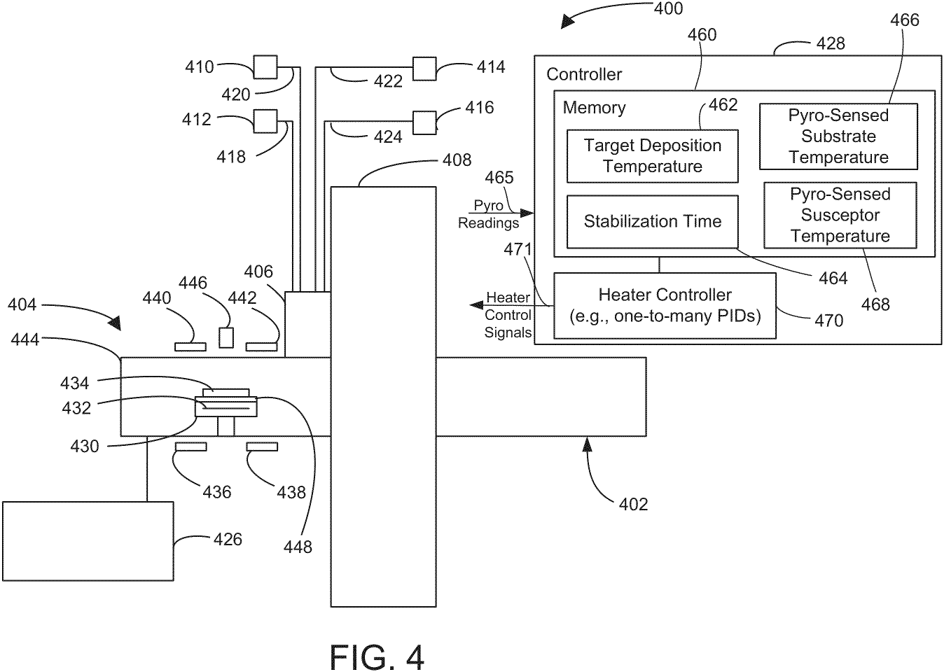

FIG. 4 illustrates an exemplary reactor system 400 in accordance with examples of the disclosure. Reactor system 400 can be used for a variety of applications, such as to perform method 100, to form structure 200, or the like. In the illustrated example, reactor system 400 includes an optional substrate handling system 402, a reaction chamber 404, a gas injection system 406, and optionally a wall 408 disposed between reaction chamber 404 and substrate handling system 402. System 400 can also include a first gas source 410, a second gas source 412, a third gas source 414 and a fourth gas source 416, an exhaust source 426, a controller 428, and a susceptor or substrate support 430. Although illustrated with four gas sources 410-416, reactor system 400 can include any suitable number of gas sources. Further, reactor system 400 can include any suitable number of reaction chambers 404, which can each be coupled to a gas injection system 406. In the case in which reactor system 400 includes multiple reaction chambers, each gas injection system can be coupled to the same gas sources 410-416 or to different gas sources. Reactor system 400 can include any suitable number of substrate handling systems 402. Reaction chamber 404 of reactor system 400 can be or include, for example, a cross flow, cold wall epitaxial reaction chamber.

Gas sources 410-416 can include, for example, various combinations of one or more precursors, one or more dopant sources, one or more etchants, and mixtures of gases, including mixtures of one or more precursors, dopant sources, and/or etchants with one or more carrier gases. By way of examples, first gas source 410 can include an etchant. Second gas source 412 can include a precursor. Exemplary etchants can include a halide, such as a chlorine-containing gas. Exemplary chlorine-containing gases include one or more gases selected from the group consisting of hydrogen chloride, chlorine gas, and the like. Exemplary precursors include silicon-containing precursors, such as trichlorosilane, dichlorosilane, silane, disilane, trisilane, silicon tetrachloride, other silicon precursors noted herein, and the like.

In some cases, one or more gas sources can include a dopant. Exemplary dopant sources include gases that include one or more of As, P, C, Ge, and B. By way of examples, the dopant source can include germane, diborane, phosphine, arsine, or phosphorus trichloride. One or more sources 410-416 can include a carrier and/or dilution gas, such as a carrier or dilution gas as described herein.

Susceptor or substrate support 430 can include one or more heaters 432 to heat a substrate 434 to a desired temperature, such as a temperature noted herein. Susceptor or substrate support 430 can also be configured to rotate (or not) during processing. In accordance with examples of the disclosure, susceptor or substrate support 430 rotates at a speed of about 60 to about 2, about 35 to about 2, or about 35 to about 15 rotations per minute. Reactor system 400 can also include one or more lamps 436-442 to heat the substrate 434 and/or a wall (e.g., wall 444) of reaction chamber 404. In addition, reactor system 400 can include one or more pyrometers 446 to measure a temperature within reaction chamber 404.

As noted above, in accordance with various examples of the disclosure, prior to processing a substrate, such as substrate 434, reaction chamber 404 can be coated with a precoat material 448 using, for example, method steps as described herein. Exhaust source 426 can include one or more vacuum pumps. During operation of reactor system 400, substrate 434 is transferred from, e.g., substrate handling system 402, to reaction chamber 404. Once substrate(s) 434 are transferred to reaction chamber 404, one or more gases from gas sources 410-416 are introduced into reaction chamber 404 via gas injection system 406. Gas injection system 406 can be used to meter and control gas flow of one or more gases from gas sources 410-416 during substrate processing and to provide desired flows of such gas(es) to multiple sites within reaction chamber 404.

Controller 428 includes electronic circuitry and software to selectively operate valves, manifolds, heaters, pumps and other components included in the system 400 such as during performance of the method 100 of FIG. 1. Such circuitry and components operate to introduce precursors, reactants, and purge gases from the respective sources 410-416. Controller 428 can control timing of gas pulse sequences, temperature of the substrate and/or reaction chamber, pressure within the reaction chamber, and various other operations to provide proper operation of the system 400. Controller 428 can include control software to electrically or pneumatically control valves to control flow of precursors, reactants and purge gases into and out of the reaction chamber 404. Controller 428 can include modules, such as a software or hardware component, e.g., a FPGA or ASIC, which performs certain tasks. A module can advantageously be configured to reside on the addressable storage medium of the control system and be configured to execute one or more processes.

More particularly, the controller 428 is adapted for performing a pyrometer controlled MWC process. To this end, the controller 428 includes memory 460 that may store software or code defining a deposition process recipe as well as a clean/etch process recipe to define temperatures, pressures, and timing of operation of system 400 components to perform deposition processes on multiple wafers between chamber cleaning processes. The memory 460 is shown to store a target deposition temperature 462 as well as a stabilization time 464. The controller 428 uses the target deposition temperature 462 to control system heaters 432-442 during stabilization as well as during deposition. The controller 428 uses the stabilization time 464 to determine when to commence deposition steps in the deposition recipe after initialization of stabilization.

The controller 428 includes a heater controller(s) 470 that is adapted to provide pyrometer control of the heaters 432-442 while stabilizing the temperature of the substrate 434 as well as during deposition steps and, in some cases, during cleaning of the chamber 404. The heater controller 470 may include one or more proportional-integral-derivative (PID) controllers each adapted to generate heater control signals 471 for one or more of the heaters 432-442 (e.g., one PID controller per heater or per bank or set of heaters). The controller 428 provides pyrometer-based control of stabilization or stabilizing steps prior to deposition by processing pyrometer readings 465 from the one or more pyrometers 446 and determining present chamber temperatures.

Particularly, the controller 428 (or heater controller 470) processes the pyrometer readings 465 to determine substrate temperatures 466 after a substrate 434 is placed on an upper or top surface of the susceptor 430 during stabilization and during deposition, and the heater controller 470 is operated to generate the heater control signals 471 to stabilize the substrate temperature 466 within a range about the target deposition temperature (e.g., within 2° C. or the like). Also, the controller 428 (or heater controller 470) acts to process the pyrometer readings 465 when a substrate 434 is removed after deposition and prior to cleaning to determine a susceptor temperature 468 (or a temperature of the top or upper surface of the susceptor 468), and this temperature 468 may be used to provide pyrometer-based control of the heaters 432-442 during the chamber cleaning or etching processes carried out by the system 400.

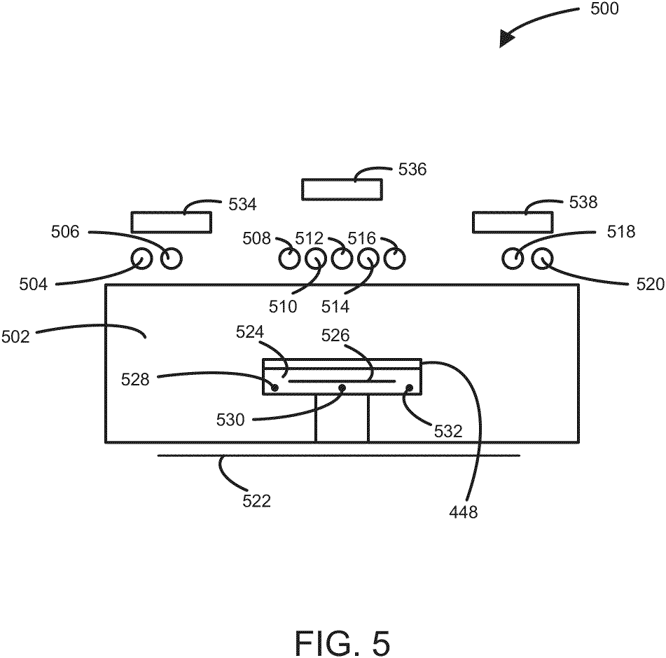

FIG. 5 illustrates another reactor system 500 in accordance with examples of the disclosure. Reactor 500 can be the same or similar to reactor system 400. In the illustrated example, reactor system 500 includes a reaction chamber 502, heaters 504-522, a susceptor 524, a heating element 526, temperature sensors 528-532 (e.g., thermocouples and the like), and temperature sensors 534-538 (e.g., pyrometers). Reaction chamber 502 can be the same or similar to reaction chamber 404.

Heaters 504-522 can be or include, for example, (e.g., infrared) heating lamps. As illustrated, lamps 504-520 can be in a first direction and one or more lamps 522 can be in a (e.g., substantially perpendicular) second direction. Further, heaters 504-522 can be segmented into one or more heating zones. For example, heaters 504, 506 can be in a first (e.g., front) zone; heaters 508-516 and optionally heater 522 can be in a second (e.g., middle, i.e., center zone); and heaters 518, 520 can be in a third (e.g., rear) zone. Each zone can include one or more heaters and is not necessarily limited to the configuration illustrated. By way of examples, each zone can include from about 1 to about 24 or about 2 to about 16 heaters. In accordance with embodiments of the disclosure, a temperature within each zone can be independently controlled by measuring a temperature-e.g., using one or more temperature sensors 534-538 and using a controller, such as controller 428. Further, another heating element 526 on or embedded within susceptor 524 can be used to control a temperature of a substrate. Heating element 526 can be independently controlled of controlled in connection with one or more zones. Such independent temperature control can be used, for example, during one or more step of method 100. In accordance with particular examples, a reactor system can include about 1 to about 24 or about 2 to about 16 linear lamps (e.g., in one or more of the zones) and one or more spot lamps in in one or more zones. The linear lamps can be, for example, silicon-controlled rectifier (SCR) linear lamps. Each linear lamp can exhibit, for example, about 10,000 W maximum output. The spot lamps can each be formed of, for example, four individual round spots and can be located, for example, below the reaction chamber. The maximum capacity of each round spot can be about 1000-2000 W.

In accordance with examples of the disclosure, such as deposition of silicon germanium, at least two or at least three temperature zones are independently controlled, e.g., by generation of control signals 471 by heater controller 470 as shown in FIG. 4 during a precoat deposition, during stabilization, during an epitaxial layer deposition process, and during chamber cleaning. By way of examples, a front (e.g., nearest the gas inlet) temperature zone can be controlled to a higher temperature (e.g., greater than 10° C. or greater than or about 25° C.) than the middle temperature zone, which can be higher than the rear temperature zone (e.g., less than 10° C. or less than or about 25° C. than a target middle zone temperature).

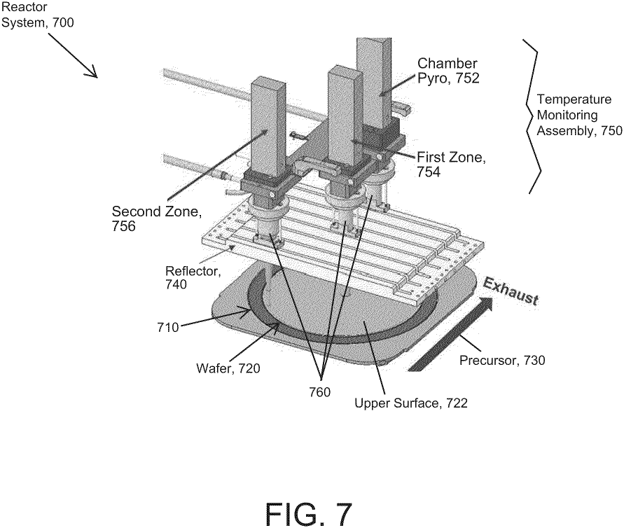

FIG. 7 illustrates a reactor system 700 using a simplified top perspective view showing a portion of components that may be provided within and adjacent to a reaction chamber configured for epitaxial (EPI) growth (e.g., growth or deposition of a SiGe layer or the like) or other deposition processes to provide pyrometer-based control during the stabilization of the substrate temperature prior to and during deposition processes. In this particular example, the system 700 is designed to achieve real-time dual-zone substrate temperature control (e.g., with a closed-loop controller design) during stabilization and deposition, but a smaller or greater number of pyrometers may be used and differing pyrometer-based control routines utilized.

Within the inner chamber of the reaction chamber of system 700, a susceptor 710 is provided for supporting (and, typically, rotating) a substrate 720. The system 700 is configured according to this description to have the capability to provide real-time temperature variation (e.g., center-to-edge differential) control between the substrate center and the edge of the substrate 720 so as to control cross-substrate film thickness variation (e.g., film roll-up or roll-down at the edge of the substrate) due to temperature differential during deposition between the center and the edge of the substrate during deposition on an upper surface 722 of the substrate 720. During deposition processes, gas flow of precursors, reactants, the like flows over the substrate 720 positioned within the reaction chamber as shown by arrow 730. The precursor(s) may include one or more of: (a) a silicon-containing precursor such as silane; (b) a germanium-containing precursor such as germane, (c) a dopant-containing precursor such as an arsenic or phosphorous-containing dopant, (d) a halide-containing gas such as hydrochloric acid, and (e) a carrier gas such as hydrogen. Heating of the substrate 720 may be provided by a heater assembly that includes a set or array of thermal or heat generators (upper or top generators (which may be lamps)) provided below a reflector 740 such as in a lamp bank (as well as a set or array of thermal or heat generators (lower or bottom generators (which may be lamps) discussed below), which is spaced apart some distance from the upper surface 722 of the substrate 720.

A temperature monitoring assembly 750 is provided that includes a chamber pyrometer 752 for measuring a temperature of the upper wall of the chamber (or quartz temperature) along with a first zone or center pyrometer 754 and a second zone or edge pyrometer 756. Each of the pyrometers 752, 754, and 756 is supported above the lamp bank, e.g., with a mounting stand 760 attached to reflector 740. The heater elements radiantly heat the substrate 720 directly or through the susceptor 710.

The heated substrate 720, and developing film on surface 722, emit electromagnetic radiation. The pyrometers 754, 756 collect electromagnetic radiation emitted from a portion of the substrate (and/or developing film) within the field of view of the pyrometer 754, 756. The center and edge pyrometers 754, 756, during their operations, have field of views or corresponding sensor areas or spots (or sense or monitor temperatures in their field of view or sensor areas/spots) on the upper surface 722 of the substrate 720 as part of sensing or reading temperatures. Each pyrometer has a field of view. In some examples the field of view of the center pyrometer 754 may be the same size as that of field of view of the edge pyrometer 756. In some examples, the field of view of the edge pyrometer 756 may be smaller than that of the center pyrometer 754. This reduces error in temperature measurements acquired by the edge pyrometer, for example, when emissivity of the substrate changes relatively rapidly in the radially outward direction. The electromagnetic radiation is collected through gaps/spaces between linear lamps in the top or upper lamp bank and, in most cases, the reflector 740 prior to transmission through the corresponding mounting stand 760. In some cases, the emitted electromagnetic radiation passes along an optical path extending between the pyrometer and the upper surface of the wafer, the optical path including (a) an optical fiber connecting the pyrometer to a mount (coupler or stand), (b) an aperture extending through the reflector, (c) a gap between heater elements, and (d) a quartz material forming the upper wall of the reaction chamber. The stands 760 are positioned on the reflector 740, when included, so that the spots/sensor areas (i.e., fields of view) of the center and edge pyrometers 754 and 756 are located in two zones of the substrate 720 or its surface 722 or in center and edge zones.

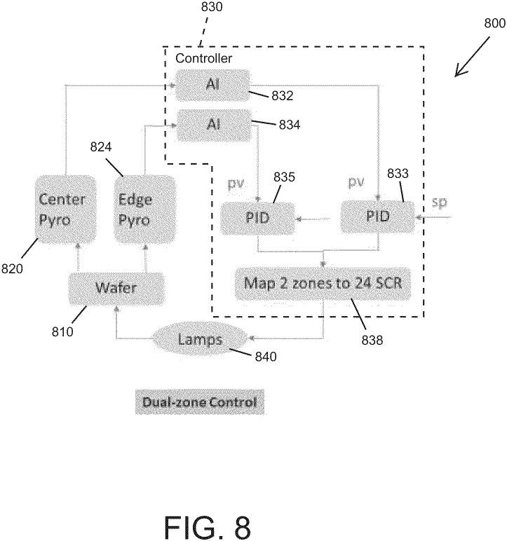

FIG. 8 illustrates a schematic of a reactor system 800 modified to include or implement dual-zone control that may be used during stabilization, deposition, chamber cleaning, and other processes carried out by operations of the reactor system 800. As shown, a plurality of lamps 840 are used to heat a substrate 810, and these lamps may be divided into and controlled as two zones or groups. A center pyrometer 820 is used to monitor temperatures of a center zone of the substrate 810 while concurrently an edge pyrometer 824 is used to monitor temperatures of an edge zone of the substrate 810. Temperature outputs of the pyrometers 820 and 824 (e.g., sensed or read temperatures or signals corresponding to temperatures) are fed to software or artificial intelligence (Al) modules 832 and 834, respectively, of a controller (e.g., a controller of a heating or heater assembly) 830.

The modules 832, 834 may act to compare the sensed or read temperatures from the pyrometers 820, 824 to desired temperature setpoints (e.g., target deposition temperature(s) used for stabilization and deposition) for the center and edge zones of the substrate 810 during a particular process (e.g., epitaxial growth), and such temperature setpoints may be stored in memory (not shown in FIG. 8) that is accessible by the controller 830, which typically would further include a processor(s) executing code or instructions to provide the functions of the Al modules 832, 834 and PID modules 833, 835.

Such processes may take relatively long periods of time to complete, such as 30 to 90 minutes for stabilizing substrate temperatures prior to initiating deposition, and the control provided by controller 830 is preferably ongoing over the entire process (including, in some cases, pre and post-deposition/growth steps). The outputs of the Al modules 832, 834 of each zone are provided to PID modules 833 and 835 to bring the read temperatures to the desired setpoint temperatures by transmitting control signals to heater control units or switches, such as silicon-controlled rectifiers (SCRs), to adjust the proportion of the overall heat lamp electric power provided to each zone of lamps 840, with each lamp in each zone typically receiving matching power levels.

The system 800 is configured to allow independent and dual-zone closed-loop temperature control. Compared to single-zone feedback control, dual-zone pyrometer control increases the independent tunability of the substrate center and edge thermal profile by automatic adjusting of the SCR power ratio by the Al modules 832, 834 and PID modules 833, 835. Given pyrometers function as non-contact and instant sensors for directly determining substrate temperatures from the amount of thermal radiation it emits, a target edge-to-center thermal profile tuning can be achieved directly on the substrate 810 with a very short transition time regardless of substrate type, chip design, and environment impact.

The dual-zone control of the present description, which may be implemented as shown in system 800 of FIG. 8, is useful for providing real-time and stable center-to-edge temperature control during stabilization after chamber cleaning and before (and during) film growth (and other substrate processing in a chamber heated by heat lamps). Examples of films deposited on the substrate 810 after a stabilization time has elapsed with heater control by controller 830 include: (a) silicon films, (b) silicon-germanium films, and (c) doped silicon films such phosphorous doped and arsenic doped films. At steady status, dual pyrometer closed-loop control enables a stable temperature at both the substrate center and at the substrate edge via real-time adjustment of silicon-controlled rectifier (SCR) power.

The pyrometer-based control described above has been implemented to demonstrate its effectiveness and advantages relative to conventional control using a susceptor thermocouple. In the demonstrations, chamber cleaning was performed after every five substrates (or wafers), and a film or layer of 400 Angstrom-thick B-doped SiGe (20% Ge) was formed during deposition. Additional fabrication specifications included a throughput of at least four wafers per hour (wph) per reaction chamber and a WTW NU% (range/2.mean) of less than 2 percent. A goal of the demonstration was to determine if pyrometer-based control can be used to reduce the stabilization time relative to thermocouple-based control to improve throughput. Thermocouple-based control was able to meet the WTW NU% (i.e., about 1.1 percent) and Ge concentration specifications while depositing a layer with a mean thickness of 400 Angstroms. Thermocouple-based control provided a throughput of 4.2 wph with a main recipe time of 770 seconds and a chamber or pre-recipe time of 406 seconds.

In contrast, pyrometer-based control was able to achieve a much higher throughput at 7.2 wph for the 5x MWC demonstration (and at 7.7 wph for a 10x MWC demonstration). The main recipe time was reduced down to 438 seconds through the use of a stabilization time of 30 seconds, which represents a reduction in time of over 300 seconds per wafer (i.e., 332 seconds in the demonstration) when compared with thermocouple-based control. Additionally, the chamber cleaning or pre-recipe time (experienced once every 5 wafers) was reduced to 310 seconds. Deposition uniformity was also improved by a surprising amount with WtW Nu% improving from 1.1 percent with thermocouple-based control to 0.36 percent with pyrometer-based control, which is well below customer specifications of less than 2 percent.

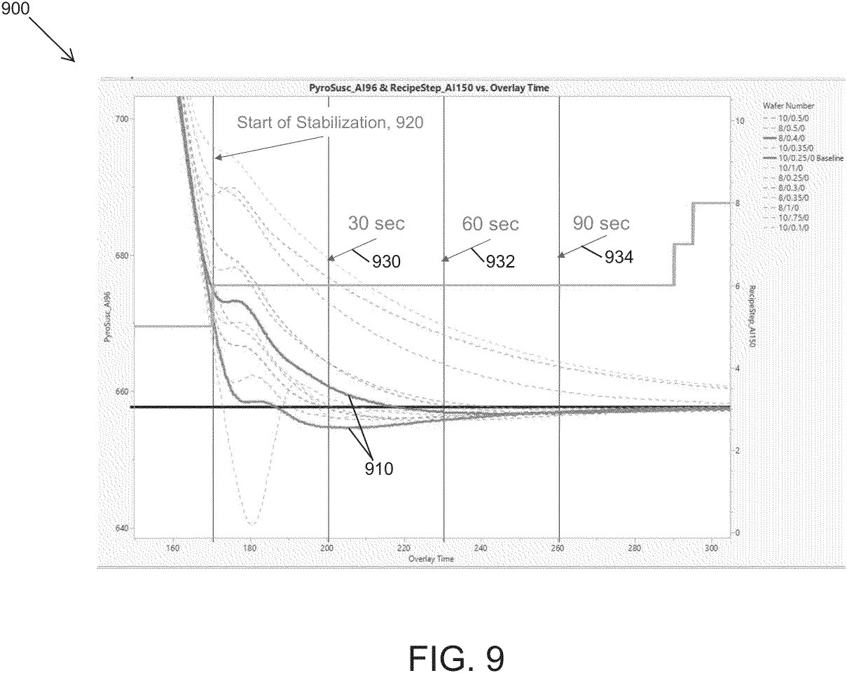

FIG. 9 is a graph 900 showing wafer temperatures prior to stabilization, during stabilization, and after stabilization (e.g., during initiation of deposition) with lines 910. As discussed above, the substrate or wafer temperatures shown with lines 910 may be read using one or more pyrometers such as a center pyrometer so as to provide direct temperature measurements. This graph 900 illustrates use of heater controllers, e.g., PIDs, that are optimized for stability after a stabilization time has elapsed, and, in the graph 900, a target deposition temperature of about 658° C. was selected for use in stabilizing the substrate temperature with pyrometer control over a reaction chamber heaters.

As shown, the substrate temperatures are significantly higher than the target deposition temperature prior to the start of stabilization at a first time (shown at arrow 920). Stabilization is carried out for a predefined time period (stabilization time) with 30 seconds shown with arrow 930, 60 seconds shown with arrow 932, and 90 seconds with arrow 934 with the heater controllers using pyrometer readings of the substrate temperature as closed-loop feedback (for PIDs or the like), and, after one of these three stabilization periods is completed, the reaction chamber initiates deposition with the heater controller acting to retain the substrate temperature at the target deposition temperature (or within a range of temperatures above and below this temperature) using pyrometer-based control. As shown with lines 910, the substrate temperature is stabilized relatively well and quickly using pyrometer-based controls over the chamber heaters such that a short stabilization time (such as in the range of 30 to 90 seconds) may be utilized rather than a long stabilization time (such as about 300 seconds) often used with thermocouple-based control.

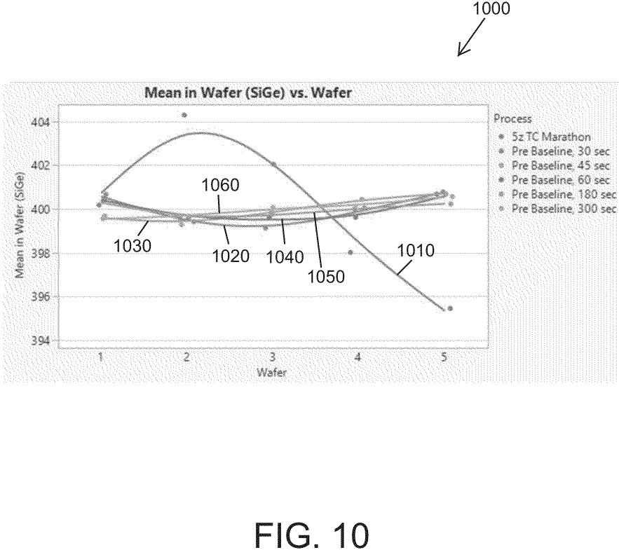

FIG. 10 is a graph 1000 showing mean in wafer (SiGe) per wafer in a five-wafer MWC process for pyrometer-based control and for thermocouple-based control. Particularly, curve 1010 shows a 5x MWC process using thermocouple control, and shows a relatively large (e.g., about 9 Angstroms) range of mean SiGe thickness for the five wafers. In contrast, curves 1020, 1030, 1040, 1050, and 1060 show a relatively small (e.g., about 2.2 Angstroms) range of mean SiGe thickness for the five wafers using stabilization times of 30 seconds, 45 seconds, 60 seconds, 180 seconds, and 300 seconds, respectively. Hence, all stabilization times tested show a large (about 4 times) improvement to thermocouple-based control.

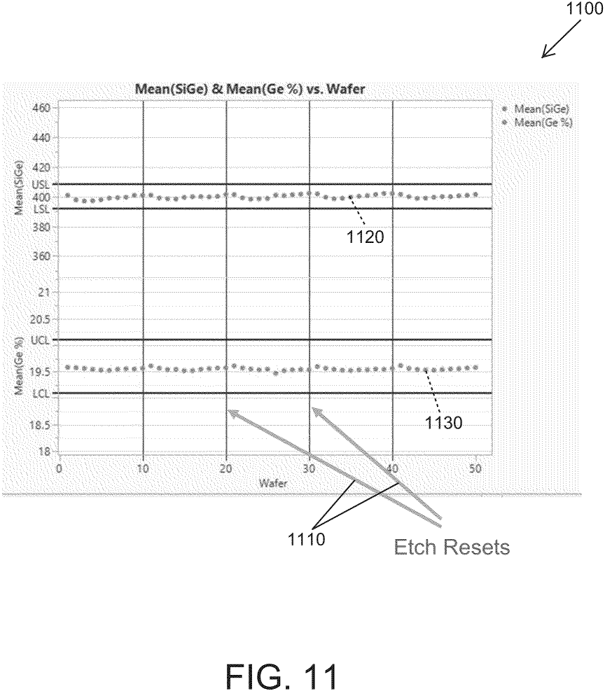

FIG. 11 is a graph showing uniformity of both mean SiGe and mean Ge percent in a ten-wafer MWC process using pyrometer-based control. Chamber cleaning or etch resets were performed after every ten wafers as shown at arrows 1110 after 20 wafers and after 30 wafers, for example. The group of dots 1120 shows mean SiGe thickness in the wafers over the demonstrative run while the group of dots 1130 shows mean Ge% in the same wafers over the run. Both values had very tight bands with mean Ge% having a range of about 0.14 percent and NU% thickness being about 0.65 percent, which shows a high deposition or within wafer uniformity when pyrometer-based control as taught herein is utilized. Hence, pyrometer control likely will lead to improved run-to-run uniformity in deposition of films/layers such as SiGe layers on a substrates or wafer. Further, the graph 1100 is useful in showing that the first wafer effect appears to be eliminated or at least mitigated using pyrometer-based controls. Thermal trend data has supported this finding as thermocouple-based control can produce a first wafer that is approximately 25 degrees hotter than later wafers (such as wafers 2 through 5 in a 5x MWC process) while pyrometer-based control has shown less than a 2 degree variation for main recipe temperatures (e.g., for deposition temperatures after stabilizing substrate temperatures using pyrometer control over reactor system heaters).

Although exemplary embodiments of the present disclosure are set forth herein, it should be appreciated that the disclosure is not so limited. For example, pyrometer arrangements are shown that include two or more pyrometers, but, in some embodiments, control (e.g., constant closed-loop feedback from the pyrometer for direct wafer temperature control) for stabilization (or other processes such as chamber cleaning) may be performed solely or nearly solely based on temperatures sensed by the center pyrometer as for stabilization purposes the temperature differential between the center of the substrate and the edge (or other portions of the wafer) are not as significant as for deposition. Use of a single pyrometer, which may be a low-cost upgrade for some legacy reactor systems, allows for stabilization using a direct temperature measurement at a single point on a wafer surface. Center and edge pyrometers further allow for stabilization using temperature differentials between points at the center and edge of the wafer surface. Three or more pyrometers may be useful in some cases to allow for stabilization using temperature gradients among points distributed between the center and edge of the wafer surface.

Although the reactor systems are described in connection with various specific configurations, the disclosure is not necessarily limited to these examples. Various modifications, variations, and enhancements of the system and method set forth herein may be made without departing from the spirit and scope of the present disclosure. The subject matter of the present disclosure includes all novel and nonobvious combinations and subcombinations of the various systems, components, and configurations, and other features, functions, acts, and/or properties disclosed herein, as well as any and all equivalents thereof.

1. A method of depositing an epitaxial material layer comprising:
cleaning a reaction chamber of a reactor system;
after the cleaning, providing a substrate within the reaction chamber;
with a heater assembly, stabilizing a temperature of the substrate relative to a target deposition temperature, wherein operating the heater assembly includes generating control signals to operate heaters in the heater assembly based on a direct measurement of the temperature of the substrate;
after the stabilizing of the temperature of the substrate, depositing an epitaxial material layer on a surface of the substrate;
for an additional number of substrates, repeating the providing a substrate within the reaction chamber, the stabilizing the temperature of the substrate, and the depositing an epitaxial material layer on the surface of the substrate; and
repeating the cleaning of the reaction chamber.

2. The method of claim 1, wherein the direct measurement of the temperature of the substrate is provided by operating a pyrometer to sense a temperature of a single point on the surface of the substrate.

3. The method of claim 1, wherein the direct measurement of the temperature of the substrate is provided by operating a center pyrometer and an edge pyrometer to sense temperatures at a center point and an edge point on the surface of the substrate.

4. The method of claim 1, wherein the direct measurement of the temperature of the substrate is provided by operating two or more pyrometers to sense temperatures at two or more points on the surface of the substrate.

5. The method of claim 2, wherein the control signals are generated by a heater controller comprising a proportional-integral-derivative (PID) controller based on a comparison of the temperature of the substrate sensed by a pyrometer to the target deposition temperature.

6. The method of claim 1, wherein the stabilizing of the temperature of the substrate is performed for a stabilization time in a range of 30 to 90 seconds.

7. The method of claim 1, wherein the step of repeating the providing a substrate within the reaction chamber, the stabilizing the temperature of the substrate, and the depositing an epitaxial material layer on the surface of the substrate is performed at least four times, whereby the step of cleaning the reaction chamber is performed after five or more substrates have been processed.

8. The method of claim 2, wherein the reaction chamber comprises a susceptor with an upper surface for supporting the substrate provided within the reaction chamber and wherein, during the cleaning of the reaction chamber, the heater assembly is operated by control signals generated in response to a temperature of the upper surface of the susceptor sensed by the pyrometer.

9. The method of claim 2, wherein, during the step of depositing an epitaxial material layer, a controller operates to generate control signals to operate the heaters in the heater assembly based on the direct measurement of the temperature of the surface of the substrate by the pyrometer.

10. The method of claim 1, wherein the epitaxial material layer comprises a silicon germanium film and wherein a range of mean thickness of the silicon germanium film is less than 3.5 Angstroms.

11. A method of depositing an epitaxial material layer comprising:
with a pyrometer, sensing a temperature of a substrate supported in a reaction chamber of a reactor system;
with a controller, comparing the temperature of the substrate to a target deposition temperature and, in response, generating control signals to control heating of at least one of the substrate and the reaction chamber;
for a stabilization time period, based on the control signals, controlling operations of a heater assembly operating to heat the substrate or the reaction chamber; and
after the stabilization time period has lapsed, depositing an epitaxial material layer on a surface of the substrate.

12. The method of claim 11, further comprising removing the substrate from the reaction chamber and supporting a next substrate within the reaction chamber, wherein the sensing, the controlling, the depositing, the removing, and the supporting steps are performed a plurality of times followed by a step of cleaning the reaction chamber.

13. The method of claim 11, wherein the control signals are generated by a heater controller comprising a proportional-integral-derivative (PID) controller based on a comparison of the temperature of the substrate sensed by the pyrometer to the target deposition temperature.

14. The method of claim 11, wherein the stabilization time period has a length in a range of 30 to 90 seconds.

15. The method of claim 11, wherein the reaction chamber comprises a susceptor with an upper surface for supporting the substrate provided within the reaction chamber, wherein the method further comprises prior to the sensing, cleaning the reaction chamber and supporting the substrate on the upper surface of the susceptor, and wherein, during the cleaning of the reaction chamber, operating the heater assembly with control signals generated by the controller in response to a temperature of the upper surface of the susceptor sensed by the pyrometer.

16. The method of claim 11, wherein, during the step of depositing an epitaxial material layer, the controller generates control signals to operate the heater assembly based on direct measurement of the temperature of the surface of the substrate by the pyrometer.

17. The method of claim 11, wherein the epitaxial material layer comprises a silicon germanium layer.

18. A system for depositing an epitaxial material layer comprising:
a reaction chamber;
in the reaction chamber, a susceptor for supporting a substrate;
a heat assembly with a plurality of heaters to heat the substrate on the susceptor;
a pyrometer directly measuring a temperature of the substrate; and
a controller controlling, after a chamber cleaning process, the plurality of heaters based on the temperature of the substrate to stabilize the temperature of the substrate relative to a target deposition temperature, wherein the controlling is performed for a stabilization time prior to initiating deposition of layer of material on the substrate supported on the susceptor.

19. The system of claim 18, wherein the stabilization time is in a range of 30 to 90 seconds, wherein the controller includes a proportional-integral-derivative (PID) controller generating control signals to control one or more heaters in the heat assembly based on a comparison of the temperature of the substrate sensed by the pyrometer to the target deposition temperature, and wherein the chamber cleaning process is performed after two or more of substrates are processed including the controller stabilizing the substrate temperature for the stabilization time prior to initiating the deposition of a layer of material on the substrate.

20. The system of claim 19, wherein the controller further controls the plurality of heaters based on the temperature of the substrate to stabilize the temperature of the substrate relative to a target deposition temperature during the deposition of the layer of material on the substrate and based on a temperature of the susceptor sensed by the pyrometer during the chamber cleaning process.
